(19) United States
(12) Patent Application Publication
(10) Pub. No.: US 2026/0082649 A1
(43) Pub. Date: Mar. 19, 2026

(54) SILICON CARBIDE EPITAXIAL SUBSTRATE, METHOD OF MANUFACTURING EPITAXIAL SUBSTRATE, AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventor: Taro ENOKIZONO, Osaka (JP)

(73) Assignee: SUMITOMO ELECTRIC INDUSTRIES, LTD., Osaka (JP)

(21) Appl. No.: 19/109,788

(22) PCT Filed: Sep. 7, 2023
(86) PCT No.: PCT/JP2023/032681

§ 371 Date: Mar. 7, 2025

(30) Foreign Application Priority Data
Sep. 13, 2022 (JP) 2022-145264

(51) Int. Cl. H10D 62/60; H01L 21/02; H10D 30/01; H10D 30/66; H10D 62/10; H10D 62/832; H10D 64/27

(52) U.S. Cl. CPC H10D 62/60; H10D 30/0297; H10D 30/668; H10D 62/124; H10D 62/8325; H10D 64/514; H10D 64/518; H10P 14/3408

(57) ABSTRACT

A silicon carbide epitaxial substrate includes a silicon carbide substrate and a silicon carbide epitaxial layer. The silicon carbide epitaxial layer is provided on the silicon carbide substrate. The silicon carbide epitaxial layer has a boundary layer, a buffer layer, and a drift layer. The boundary layer is provided on the silicon carbide substrate. The buffer layer is provided on the boundary layer. The drift layer is provided on the buffer layer. A concentration of an n type impurity in the buffer layer is 3×10¹⁸/cm³ or more. A concentration of an n type impurity in the boundary layer is higher than the concentration of the n type impurity in the buffer layer.

### TECHNICAL FIELD

The present disclosure relates to a silicon carbide epitaxial substrate, a method of manufacturing an epitaxial substrate, and a method of manufacturing a silicon carbide semiconductor device. The present application claims priority based on Japanese Patent Application No. 2022-145264 filed on Sep. 13, 2022. The entire contents of the Japanese Patent Application are incorporated herein by reference.

### BACKGROUND ART

WO 2018/043300 (PTL 1) discloses a method of manufacturing a silicon carbide semiconductor device, the method including a step of measuring a thickness of an epitaxial layer using Fourier transform infrared spectroscopy.

### CITATION LIST

### Patent Literature

PTL 1: WO 2018/043300

### SUMMARY OF INVENTION

A silicon carbide epitaxial substrate according to the present disclosure includes a silicon carbide substrate and a silicon carbide epitaxial layer. The silicon carbide epitaxial layer is provided on the silicon carbide substrate. The silicon carbide epitaxial layer includes a boundary layer, a buffer layer, and a drift layer. The boundary layer is provided on the silicon carbide substrate. The buffer layer is provided on the boundary layer. The drift layer is provided on the buffer layer. A concentration of an n type impurity in the buffer layer is 3×10¹⁸/cm³ or more. A concentration of an n type impurity in the boundary layer is higher than the concentration of the n type impurity in the buffer layer.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view along a line II-II of FIG. 1.

FIG. 3 is a schematic diagram showing a relation between a concentration of an n type impurity and a depth in the silicon carbide epitaxial substrate according to the present embodiment.

FIG. 4 is a schematic cross sectional view showing a configuration of an epitaxial substrate according to the present embodiment.

FIG. 5 is a schematic cross sectional view showing a configuration of an epitaxial substrate according to a modification of the present embodiment.

FIG. 6 is a partial schematic cross sectional view showing a configuration of a manufacturing apparatus for the epitaxial substrate.

FIG. 7 is a flowchart schematically showing a method of manufacturing the epitaxial substrate according to the present embodiment.

FIG. 8 is a schematic cross sectional view showing a step of measuring a first distance.

FIG. 9 is a flowchart schematically showing a method of manufacturing a silicon carbide semiconductor device according to the present embodiment.

FIG. 10 is a schematic cross sectional view showing a step of forming a body region.

FIG. 11 is a schematic cross sectional view showing a step of forming a source region.

FIG. 12 is a schematic cross sectional view showing a step of forming a trench in a fifth main surface of a second silicon carbide epitaxial layer.

FIG. 13 is a schematic cross sectional view showing a step of forming a gate insulating film.

FIG. 14 is a schematic cross sectional view showing a step of forming a gate electrode and an interlayer insulating film.

FIG. 15 is a schematic cross sectional view showing a configuration of the silicon carbide semiconductor device according to the present embodiment.

FIG. 16 is a schematic cross sectional view showing a step of measuring a first distance in a silicon carbide epitaxial substrate according to a comparative example.

FIG. 17 is a graph showing a measurement result in a silicon carbide epitaxial substrate according to a sample 1 by an FTIR.

FIG. 18 is a graph showing a measurement result in a silicon carbide epitaxial substrate according to a sample 2 by the FTIR.

### DETAILED DESCRIPTION

### Problem to be Solved by the Present Disclosure

An object of the present disclosure is to provide a silicon carbide epitaxial substrate, a method of manufacturing an epitaxial substrate, and a method of manufacturing a silicon carbide semiconductor device, so as to improve precision of measurement for a thickness of a silicon carbide epitaxial layer.

### Advantageous Effect of the Present Disclosure

According to the present disclosure, it is possible to provide a silicon carbide epitaxial substrate, a method of manufacturing an epitaxial substrate, and a method of manufacturing a silicon carbide semiconductor device, so as to improve precision of measurement for a thickness of a silicon carbide epitaxial layer.

### Description of Embodiments

First, embodiments of the present disclosure are listed and described.

(1) A silicon carbide epitaxial substrate 100 according to the present disclosure includes a first silicon carbide substrate 30 and a first silicon carbide epitaxial layer 40. First silicon carbide epitaxial layer 40 is provided on first silicon carbide substrate 30. First silicon carbide epitaxial layer 40 includes a first boundary layer 41, a first buffer layer 42, and a first drift layer 43. First boundary layer 41 is provided on first silicon carbide substrate 30. First buffer layer 42 is provided on first boundary layer 41. First drift layer 43 is provided on first buffer layer 42. A concentration C2 of an n type impurity in first buffer layer 42 is 3×10¹⁸/cm³ or more. A concentration C3 of an n type impurity in first boundary layer 41 is higher than concentration C2 of the n type impurity in first buffer layer 42.

(2) In silicon carbide epitaxial substrate 100 according to (1), concentration C3 of the n type impurity in first boundary layer 41 may be higher than a concentration C4 of an n type impurity in first silicon carbide substrate 30.

(3) In silicon carbide epitaxial substrate 100 according to (1) or (2), a value obtained by subtracting concentration C2 of the n type impurity in first buffer layer 42 from concentration C3 of the n type impurity in first boundary layer 41 may be 1×10¹⁸/cm³ or more.

(4) In silicon carbide epitaxial substrate 100 according to any one of (1) to (3), a thickness T1 of first boundary layer 41 may be 0.1 μm or more and 5 μm or less.

(5) In silicon carbide epitaxial substrate 100 according to any one of (1) to (4), concentration C2 of the n type impurity in first buffer layer 42 may be higher than a concentration C1 of an n type impurity in first drift layer 43.

(6) In silicon carbide epitaxial substrate 100 according to any one of (1) to (5), concentration C3 of the n type impurity in first boundary layer 41 may be 5×10¹⁸/cm³ or more and 1×10²⁰/cm³ or less.

(7) In silicon carbide epitaxial substrate 100 according to any one of (1) to (6), concentration C2 of the n type impurity in first buffer layer 42 may be 1×10¹⁹/cm³ or less.

(8) In silicon carbide epitaxial substrate 100 according to any one of (1) to (7), a concentration C1 of an n type impurity in first drift layer 43 may be 1×10¹⁵/cm³ or more and 5×10¹⁶/cm³ or less.

(9) A method of manufacturing an epitaxial substrate 200 according to the present disclosure includes the following steps. Silicon carbide epitaxial substrate 100 according to any one of (1) to (8) is prepared. A distance E1 from an interface 9 between first boundary layer 41 and first buffer layer 42 to a surface (first main surface 1) of silicon carbide epitaxial substrate 100 is measured using silicon carbide epitaxial substrate 100. A growth condition is determined based on distance E1 measured. Epitaxial growth is performed using the growth condition determined.

(10) A method of manufacturing a silicon carbide semiconductor device 400 according to the present disclosure includes the following steps. An epitaxial substrate 200 is manufactured using the method of manufacturing an epitaxial substrate 200 according to (9). Epitaxial substrate 200 is processed.

### Details of Embodiments of the Present Disclosure

The following describes an embodiment of the present disclosure with reference to figures. It should be noted that in the below-mentioned figures, the same or corresponding portions are given the same reference characters and are not described repeatedly. Regarding crystallographic indications in the present specification, an individual orientation is represented by [], a group orientation is represented by <>, and an individual plane is represented by (), and a group plane is represented by {}. In addition, a negative index is supposed to be crystallographically indicated by putting “-” (bar) above a numeral, but is indicated by putting the negative sign before the numeral in the present specification.

### (Silicon Carbide Epitaxial Substrate)

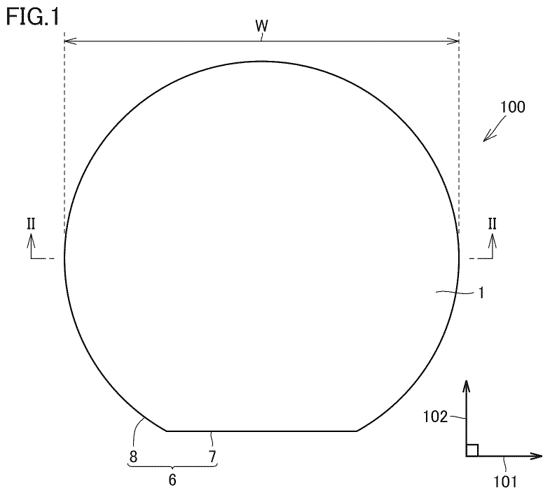

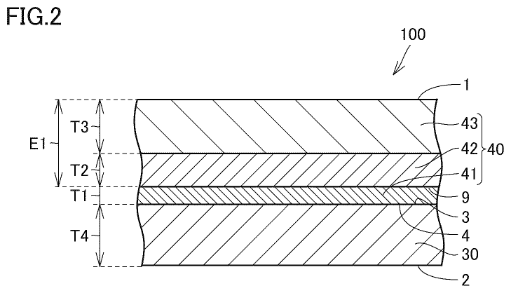

FIG. 1 is a schematic plan view showing a configuration of a silicon carbide epitaxial substrate 100 according to the present embodiment. FIG. 2 is a schematic cross sectional view along a line II-II of FIG. 1. As shown in FIGS. 1 and 2, silicon carbide epitaxial substrate 100 according to the present embodiment has a first silicon carbide substrate 30 and a first silicon carbide epitaxial layer 40. First silicon carbide epitaxial layer 40 is provided on first silicon carbide substrate 30. First silicon carbide epitaxial layer 40 is in contact with first silicon carbide substrate 30. First silicon carbide epitaxial layer 40 has a first main surface 1.

First silicon carbide epitaxial layer 40 constitutes a front surface (first main surface 1) of silicon carbide epitaxial substrate 100. First silicon carbide substrate 30 constitutes a backside surface (second main surface 2) of silicon carbide epitaxial substrate 100. As shown in FIG. 1, silicon carbide epitaxial substrate 100 has an outer peripheral edge 6. Outer peripheral edge 6 has, for example, an orientation flat 7 and an arc-shaped portion 8.

As shown in FIG. 1, orientation flat 7 is in the form of a straight line as viewed in the direction perpendicular to first main surface 1. Orientation flat 7 extends along a first direction 101. Arc-shaped portion 8 is contiguous to orientation flat 7. Arc-shaped portion 8 has an arc shape as viewed in the direction perpendicular to first main surface 1.

As shown in FIG. 1, as viewed in the direction perpendicular to first main surface 1, first main surface 1 is expanded along each of first direction 101 and a second direction 102. As viewed in the direction perpendicular to first main surface 1, second direction 102 is a direction perpendicular to first direction 101.

First direction 101 is, for example, a <11-20> direction. First direction 101 may be, for example, a [11-20] direction. First direction 101 may be, for example, a direction obtained by projecting the <11-20> direction onto first main surface 1. From another viewpoint, it can be said that first direction 101 may be a direction including a <11-20> direction component, for example.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

First main surface 1 may be a {0001} plane or a plane inclined with respect to the {0001} plane. When first main surface 1 is inclined with respect to the {0001} plane, an inclination angle (off angle) thereof with respect to the {0001} plane is, for example, more than 0°and 8°or less. When first main surface 1 is inclined with respect to the {0001} plane, an inclination direction (off direction) of first main surface 1 is, for example, the <11-20> direction. The off angle may be 2° or more and 6°or less.

As shown in FIG. 1, maximum diameter W (diameter) of first main surface 1 is not particularly limited, but is, for example, 100 mm (4 inches) or more. Maximum diameter W may be 125 mm (5 inches) or more, 150 mm (6 inches) or more, or 200 mm (8 inches) or more. Maximum diameter W is not particularly limited, but may be, for example, 400 mm (16 inches) or less. As viewed in the direction perpendicular to first main surface 1, maximum diameter W is the maximum straight line between two different points on outer peripheral edge 6.

It should be noted that in the present specification, 4 inches mean 100 mm or 101.6 mm (4 inches×25.4 mm/inch). 6 inches mean 150 mm or 152.4 mm (6 inches×25.4 mm/inch). 8 inches mean 200 mm or 203.2 mm (8 inches×25.4 mm/inch). 16 inches mean 400 mm or 406.4 mm (16 inches×25.4 mm/inch).

As shown in FIG. 2, first silicon carbide substrate 30 has a second main surface 2 and a third main surface 3. Third main surface 3 is located opposite to second main surface 2. Second main surface 2 is separated from first silicon carbide epitaxial layer 40. Third main surface 3 is in contact with first silicon carbide epitaxial layer 40. The polytype of the silicon carbide of first silicon carbide substrate 30 is, for example, 4 H. Similarly, the polytype of first silicon carbide epitaxial layer 40 is, for example, 4 H.

As shown in FIG. 2, first silicon carbide epitaxial layer 40 has a fourth main surface 4. Fourth main surface 4 is located opposite to first main surface 1. First silicon carbide epitaxial layer 40 is in contact with first silicon carbide substrate 30 at fourth main surface 4. First silicon carbide epitaxial layer 40 has a first boundary layer 41, a first buffer layer 42, and a first drift layer 43. First drift layer 43 may be a single layer or two or more layers.

First boundary layer 41 is provided on first silicon carbide substrate 30. First boundary layer 41 is in contact with first silicon carbide substrate 30. First boundary layer 41 constitutes fourth main surface 4. The thickness of first boundary layer 41 is defined as a first thickness T1. First thickness T1 is, for example, 0.1 μm. First thickness T1 may be, for example, 0.1 μm or more and 5 μm or less. First thickness T1 is not particularly limited, but may be, for example, 0.3 μm or more, or 0.5 μm or more. First thickness T1 is not particularly limited, but may be, for example, 4 μm or less, or 3 μm or less.

First buffer layer 42 is provided on first boundary layer 41. First buffer layer 42 is in contact with first boundary layer 41. The thickness of first buffer layer 42 is defined as a second thickness T2. Second thickness T2 may be more than first thickness T1. Second thickness T2 is, for example, 0.1 μm or more and 10 μm or less. Second thickness T2 is not particularly limited, but may be, for example, 0.2 μm or more, or 0.5 μm or more. Second thickness T2 is not particularly limited, but may be, for example, 5 μm or less, or 2 μm or less.

First drift layer 43 is provided on first buffer layer 42. First drift layer 43 is in contact with first buffer layer 42. First drift layer 43 constitutes first main surface 1. The thickness of first drift layer 43 is defined as a third thickness T3. Third thickness T3 is more than second thickness T2. Third thickness T3 is, for example, 5 μm or more and 100 μm or less. Third thickness T3 is not particularly limited, but may be, for example, 10 μm or more, or 20 μm or more. Third thickness T3 is not particularly limited, but may be, for example, 80 μm or less or 60 μm or less.

The thickness of first silicon carbide substrate 30 is defined as a fourth thickness T4. Fourth thickness T4 may be more than third thickness T3. Fourth thickness T4 is, for example, 200 μm or more and 600 μm or less. Fourth thickness T4 is not particularly limited, but may be, for example, 250 μm or more, or 300 μm or more. Fourth thickness T4 is not particularly limited, but may be, for example, 550 μm or less, or 500 μm or less.

An interface between first boundary layer 41 and first buffer layer 42 is defined as a first interface 9. A distance from first interface 9 to the surface (first main surface 1) of first silicon carbide epitaxial layer 40 is defined as first distance E1. In other words, first distance E1 is the thickness of first silicon carbide epitaxial layer 40 other than first boundary layer 41. First distance E1 is, for example, a total value of second thickness T2 and third thickness T3.

### (Concentration of n Type Impurity)

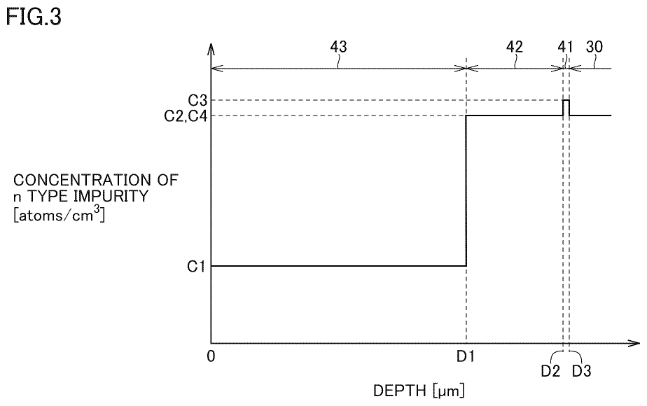

FIG. 3 is a schematic diagram showing a relation between a concentration of an n type impurity and a depth in silicon carbide epitaxial substrate 100 according to the present embodiment. In FIG. 3, the vertical axis represents the concentration of the n type impurity, and the horizontal axis represents the depth in the thickness direction. The vertical axis is an axis of common logarithm scale. The horizontal axis is an axis of a linear scale. In the present specification, the depth means a distance from first main surface 1 in the thickness direction. The depth is increased toward second main surface 2 with first main surface 1 being regarded as 0.

In FIG. 3, a position at the depth of 0 corresponds to first main surface 1. A region from first main surface 1 to a first depth D1 corresponds to first drift layer 43. In other words, first depth D1 corresponds to third thickness T3. A region from first depth D1 to a second depth D2 corresponds to first buffer layer 42. In other words, a value obtained by subtracting first depth D1 from second depth D2 is second thickness T2. A region from second depth D2 to third depth D3 corresponds to first boundary layer 41. In other words, a value obtained by subtracting second depth D2 from third depth D3 is first thickness T1. A region deeper than third depth D3 corresponds to first silicon carbide substrate 30.

As shown in FIG. 3, first drift layer 43 includes an n type impurity such as nitrogen (N), for example. The conductivity type of first drift layer 43 is, for example, n type. The concentration of the n type impurity in first drift layer 43 is defined as a first concentration C1.

First concentration C1 is, for example, 2×10¹⁶/cm³. First concentration C1 may be, for example, 1×10¹⁵/cm³ or more and 5×10¹⁶/cm³ or less. First concentration C1 is not particularly limited, but may be, for example, 3×10¹⁵/cm³ or more, or 5×10¹⁵/cm³ or more. First concentration C1 is not particularly limited, but may be, for example, 4×10¹⁶/cm³ or less, or 3×10¹⁶/cm³ or less.

As shown in FIG. 3, first buffer layer 42 includes an n type impurity such as nitrogen. The conductivity type of first buffer layer 42 is, for example, n type. The concentration of the n type impurity in first buffer layer 42 is defined as a second concentration C2. Second concentration C2 is higher than first concentration C1.

Second concentration C2 is, for example, 7×10¹⁸/cm³. Second concentration C2 is 3×10¹⁸/cm³ or more. Second concentration C2 is not particularly limited, but may be, for example, 5×10¹⁸/cm³ or more, or 7×10¹⁸/cm³ or more. Second concentration C2 is not particularly limited, but may be, for example, 1×10¹⁹/cm³ or less or 8×10¹⁸/cm³ or less.

As shown in FIG. 3, first boundary layer 41 includes an n type impurity such as nitrogen. The conductivity type of first boundary layer 41 is, for example, n type. The concentration of the n type impurity in first boundary layer 41 is defined as a third concentration C3.

Third concentration C3 is, for example, 1×10¹⁹/cm³. Third concentration C3 may be, for example, 5×10¹⁸/cm³ or more and 1×10²⁰/cm³ or less. Third concentration C3 is not particularly limited, but may be, for example, 7×10¹⁸/cm³ or more, or 9×10¹⁸/cm³ or more. Third concentration C3 is not particularly limited, but may be, for example, 7×10¹⁹/cm³ or less, or 3×10¹⁹/cm³ or less.

Third concentration C3 is higher than second concentration C2. A value obtained by subtracting second concentration C2 from third concentration C3 is, for example, 3×10¹⁸/cm³. The value obtained by subtracting second concentration C2 from third concentration C3 may be, for example, 1×10¹⁸/cm³ or more. The value obtained by subtracting second concentration C2 from third concentration C3 is not particularly limited, but may be, for example, 3×10¹⁸/cm³ or more, or 5×10¹⁸/cm³ or more. The value obtained by subtracting second concentration C2 from third concentration C3 is not particularly limited, but may be, for example, 1×10²⁰/cm³ or less, or 5×10¹⁹/cm³ or less.

As shown in FIG. 3, first silicon carbide substrate 30 includes, for example, an n type impurity such as nitrogen. The conductivity type of first silicon carbide substrate 30 is n type, for example. The concentration of the n type impurity in first silicon carbide substrate 30 is defined as a fourth concentration C4. Fourth concentration C4 is, for example, 7×10¹⁸/cm³. Fourth concentration C4 may be, for example, 3×10¹⁸/cm³ or more and 1×10¹⁹/cm³ or less.

An absolute value of a value obtained by subtracting second concentration C2 from fourth concentration C4 is less than a value obtained by subtracting second concentration C2 from third concentration C3. The absolute value of the value obtained by subtracting second concentration C2 from fourth concentration C4 is, for example, 1×10¹⁷/cm³ or more and 1×10¹⁸/cm³ or less. Fourth concentration C4 may be substantially the same as second concentration C2. Fourth concentration C4 is higher than first concentration C1. Third concentration C3 is higher than fourth concentration C4.

The concentration of the n type impurity is measured by secondary ion mass spectrometry (SIMS), for example. In the SIMS, for example, IMS7f, which is a secondary ion mass spectrometer provided by Cameca, can be used. As measurement conditions in the SIMS, for example, there can be used such measurement conditions that a primary ion is O₂⁺ and primary ion energy is 8 keV.

### (Configuration of Epitaxial Substrate)

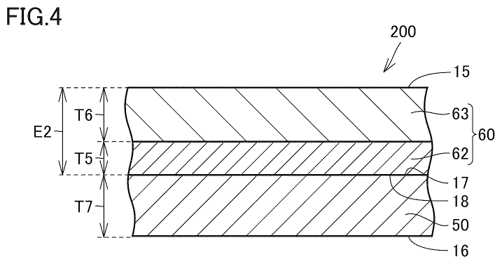

Next, a configuration of an epitaxial substrate according to the present embodiment will be described. FIG. 4 is a schematic cross sectional view showing the configuration of the epitaxial substrate according to the present embodiment. As shown in FIG. 4, an epitaxial substrate 200 has a fifth main surface 15 and a sixth main surface 16. Sixth main surface 16 is located opposite to fifth main surface 15.

Epitaxial substrate 200 has a second silicon carbide substrate 50 and a second silicon carbide epitaxial layer 60. Second silicon carbide substrate 50 has sixth main surface 16 and a seventh main surface 17. Seventh main surface 17 is located opposite to sixth main surface 16. The thickness of second silicon carbide substrate 50 is defined as a seventh thickness T7. The polytype of the silicon carbide of second silicon carbide substrate 50 is, for example, 4 H.

As shown in FIG. 4, second silicon carbide epitaxial layer 60 is provided on second silicon carbide substrate 50. Second silicon carbide epitaxial layer 60 is in contact with second silicon carbide substrate 50. Second silicon carbide epitaxial layer 60 has fifth main surface 15 and an eighth main surface 18. Second silicon carbide epitaxial layer 60 is in contact with second silicon carbide substrate 50 at eighth main surface 18. The polytype of the silicon carbide of second silicon carbide epitaxial layer 60 is, for example, 4 H.

Second silicon carbide epitaxial layer 60 has a second buffer layer 62 and a second drift layer 63. Second buffer layer 62 is provided, for example, on second silicon carbide substrate 50. Second buffer layer 62 is in contact with, for example, second silicon carbide substrate 50. The thickness of second buffer layer 62 is defined as a fifth thickness T5. Fifth thickness T5 is smaller than seventh thickness T7.

Second drift layer 63 is provided on second buffer layer 62. Second drift layer 63 is in contact with second buffer layer 62. Second drift layer 63 constitutes fifth main surface 15. The thickness of second drift layer 63 is defined as a sixth thickness T6. Sixth thickness T6 is larger than fifth thickness T5.

A distance from eighth main surface 18 to fifth main surface 15 is defined as a second distance E2. In other words, second distance E2 is the thickness of second silicon carbide epitaxial layer 60. Second distance E2 is, for example, a total value of fifth thickness T5 and sixth thickness T6.

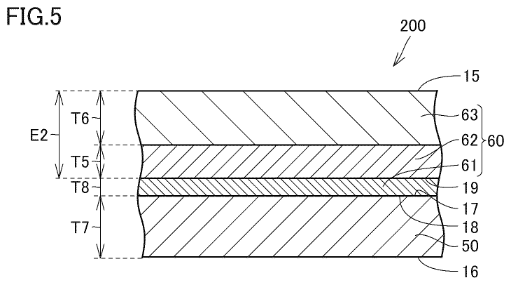

It should be noted that it has been described above that second silicon carbide epitaxial layer 60 has second buffer layer 62 and second drift layer 63; however, the configuration of epitaxial substrate 200 is not limited to the above-described configuration. FIG. 5 is a schematic cross sectional view showing a configuration of an epitaxial substrate 200 according to a modification of the present embodiment. As shown in FIG. 5, second silicon carbide epitaxial layer 60 may have a second boundary layer 61. Second boundary layer 61 is provided between second silicon carbide substrate 50 and second buffer layer 62. An interface between second boundary layer 61 and second buffer layer 62 is defined as a second interface 19. The thickness of second boundary layer 61 is defined as an eighth thickness T8. Fifth thickness T5 may be more than eighth thickness T8.

When epitaxial substrate 200 has second boundary layer 61, second distance E2 is defined as a distance from an interface (second interface 19) between second boundary layer 61 and second buffer layer 62 to a surface (fifth main surface 15) of second silicon carbide epitaxial layer 60. The configuration of epitaxial substrate 200 may be substantially the same as the configuration of silicon carbide epitaxial substrate 100 (see FIG. 2).

Second silicon carbide substrate 50 corresponds to first silicon carbide substrate 30 (see FIG. 2). Second silicon carbide epitaxial layer 60 corresponds to first silicon carbide epitaxial layer 40 (see FIG. 2). Second boundary layer 61 corresponds to first boundary layer 41 (see FIG. 2). Second buffer layer 62 corresponds to first buffer layer 42 (see FIG. 2). Second drift layer 63 corresponds to first drift layer 43 (see FIG. 2). Fifth main surface 15 corresponds to first main surface 1 (see FIG. 2). Sixth main surface 16 corresponds to second main surface 2 (see FIG. 2).

### (Manufacturing Apparatus for Epitaxial Substrate)

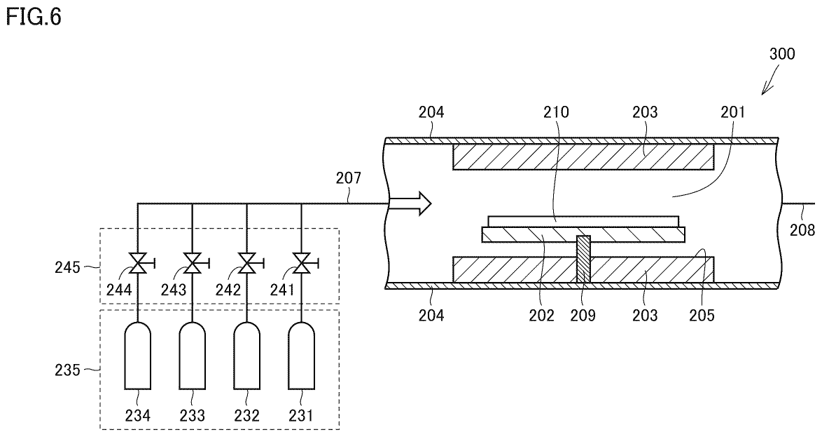

Next, a configuration of a manufacturing apparatus for the epitaxial substrate will be described. FIG. 6 is a partial schematic cross sectional view showing a configuration of the manufacturing apparatus for the epitaxial substrate. A manufacturing apparatus 300 for the epitaxial substrate is, for example, a hot wall type lateral CVD (Chemical Vapor Deposition) apparatus. As shown in FIG. 6, manufacturing apparatus 300 for the epitaxial substrate mainly has a reaction chamber 201, a gas supply unit 235, a control unit 245, a heating element 203, a quartz tube 204, a heat insulating material (not shown), and an induction heating coil (not shown).

Heating element 203 has, for example, a tubular shape, and forms reaction chamber 201 therein. Heating element 203 is composed of graphite, for example. Heating element 203 is provided inside quartz tube 204. The heat insulating material surrounds the outer periphery of heating element 203. The induction heating coil is wound, for example, along the outer peripheral surface of quartz tube 204. The induction heating coil can be supplied with an alternating current by an external power supply (not shown). Thus, heating element 203 is inductively heated. As a result, reaction chamber 201 is heated by heating element 203.

Reaction chamber 201 is a formed space surrounded by an inner wall surface 205 of heating element 203. A susceptor 210 that holds the silicon carbide substrate is provided in reaction chamber 201. Susceptor 210 is composed of silicon carbide. The silicon carbide substrate is placed on susceptor 210. Susceptor 210 is disposed on a stage 202. Stage 202 is rotatably supported by a rotation shaft 209. When stage 202 is rotated, susceptor 210 is rotated.

Manufacturing apparatus 300 for silicon carbide epitaxial substrate 100 further has a gas introduction port 207 and a gas discharging port 208. Gas discharging port 208 is connected to a gas discharging pump (not shown). An arrow in FIG. 6 indicates a flow of gas. The gas is introduced from gas introduction port 207 into reaction chamber 201 and is discharged from gas discharging port 208. Pressure in reaction chamber 201 is adjusted in accordance with a balance between an amount of supply of the gas and an amount of discharging of the gas.

Gas supply unit 235 is configured to supply reaction chamber 201 with a mixed gas including a source gas, a dopant gas, and a carrier gas. Specifically, gas supply unit 235 includes, for example, a first gas supply unit 231, a second gas supply unit 232, a third gas supply unit 233, and a fourth gas supply unit 234.

First gas supply unit 231 is configured to supply a first gas including carbon atoms, for example. First gas supply unit 231 is, for example, a gas cylinder provided with the first gas. The first gas is, for example, propane (C₃H₈) gas. The first gas may be, for example, methane (CH₄) gas, ethane (C₂H₆) gas, acetylene (C₂H₂) gas, or the like.

Second gas supply unit 232 is configured to supply a second gas including, for example, silicon atoms. Second gas supply unit 232 is, for example, a gas cylinder provided with the second gas. The second gas is, for example, silane (SiH₄) gas. The second gas may be a mixed gas of the silane gas and a gas other than silane.

Third gas supply unit 233 is configured to supply a third gas including, for example, nitrogen atoms. Third gas supply unit 233 is, for example, a gas cylinder provided with the third gas. The third gas is a doping gas. The third gas is, for example, ammonia gas. The ammonia gas is more likely to be thermally decomposed than nitrogen gas having a triple bond.

Fourth gas supply unit 234 is configured to supply a fourth gas (carrier gas) such as hydrogen, for example. Fourth gas supply unit 234 is, for example, a gas cylinder provided with hydrogen. The fourth gas may be argon gas.

Control unit 245 is configured to control a flow rate of the mixed gas to be supplied from gas supply unit 235 to reaction chamber 201. Specifically, control unit 245 may include a first gas flow rate control unit 241, a second gas flow rate control unit 242, a third gas flow rate control unit 243, and a fourth gas flow rate control unit 244. Each control unit may be, for example, an MFC (mass flow controller). Control unit 245 is disposed between gas supply unit 235 and gas introduction port 207.

### (Method of Manufacturing Epitaxial Substrate)

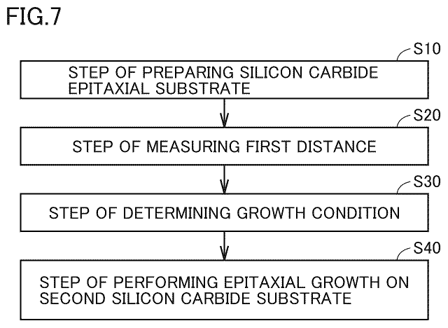

Next, a method of manufacturing epitaxial substrate 200 according to the present embodiment will be described. FIG. 7 is a flowchart schematically showing the method of manufacturing epitaxial substrate 200 according to the present embodiment. As shown in FIG. 7, the method of manufacturing epitaxial substrate 200 according to the present embodiment mainly includes: a step (S10) of preparing the silicon carbide epitaxial substrate; a step (S20) of measuring the first distance; a step (S30) of determining a growth condition; and a step (S40) of performing epitaxial growth on the second silicon carbide substrate.

First, the step (S10) of preparing the silicon carbide epitaxial substrate is performed. For example, a silicon carbide single crystal having a polytype of 4 H is produced by a sublimation method. Next, the silicon carbide single crystal is sliced by, for example, a wire saw to prepare first silicon carbide substrate 30. First silicon carbide substrate 30 includes, for example, an n type impurity such as nitrogen. The conductivity type of first silicon carbide substrate 30 is n type, for example. Next, mechanical polishing is performed onto first silicon carbide substrate 30. Next, chemical mechanical polishing is performed onto first silicon carbide substrate 30.

Next, first silicon carbide epitaxial layer 40 is formed on first silicon carbide substrate 30. Specifically, first silicon carbide epitaxial layer 40 is formed by epitaxial growth on third main surface 3 of first silicon carbide substrate 30 using the hot wall type lateral CVD apparatus shown in FIG. 6. Specifically, first boundary layer 41 is formed on third main surface 3. First buffer layer 42 is formed on first boundary layer 41. First drift layer 43 is formed on first buffer layer 42.

In the epitaxial growth, for example, silane (SiH₄) and propane (C₃H₈) are each used as a source gas, and hydrogen (H₂) is used as a carrier gas. The temperature of the epitaxial growth is, for example, about 1400° C. or more and 1700° C. or less. In the epitaxial growth, an n type impurity such as nitrogen is introduced into first silicon carbide epitaxial layer 40.

A condition for the flow rate of the source gas, the flow rate of the dopant gas, the flow rate of the carrier gas, and the time of the epitaxial growth when forming first buffer layer 42 and first drift layer 43 is defined as a first growth condition. In this way, silicon carbide epitaxial substrate 100 is prepared.

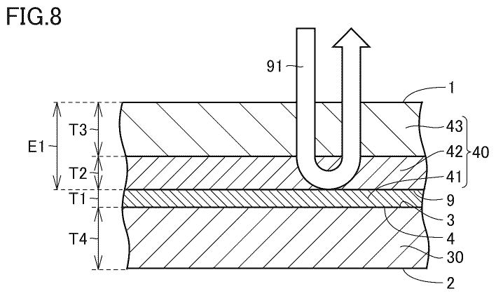

Next, the step (S20) of measuring the first distance is performed. FIG. 8 is a schematic cross sectional view showing the step of measuring the first distance. In the step (S20) of measuring the first distance, the distance (first distance E1) from the interface (first interface 9) between first boundary layer 41 and first buffer layer 42 to the surface (first main surface 1) of the first silicon carbide epitaxial layer is measured using silicon carbide epitaxial substrate 100. In other words, the total value of thickness T2 of first buffer layer 42 and thickness T3 of first drift layer 43 is measured.

First distance E1 is measured using an FTIR (Fourier Transform InfraRed spectrometer). The measurement of first distance E1 by the FTIR is performed using an optical constant difference caused by a carrier concentration difference between first buffer layer 42 and first boundary layer 41. Specifically, as shown in FIG. 8, first main surface 1 is irradiated with infrared light. Part of the infrared light travels along a first arrow 91. Specifically, part of the infrared light is reflected at the interface (first interface 9) between first boundary layer 41 and first buffer layer 42. The infrared light (first arrow 91) reflected at first interface 9 and the infrared light reflected at first main surface 1 are measured and analyzed as reflected light from silicon carbide epitaxial substrate 100, thereby measuring first distance E1.

In the FTIR, for example, a Fourier transform infrared spectrometer (IRPrestige-21) provided by Shimadzu Corporation can be used as a measurement device. A measurement wavenumber range is, for example, a range from 4700 cm⁻¹ to 650 cm⁻¹. A calculation wavenumber range is, for example, a range from 3400 cm⁻¹ to 2400 cm⁻¹. A wavenumber interval is, for example, 4 cm⁻¹. An incident angle of the infrared light is, for example, 25°.

Next, the step (S30) of determining the growth condition is performed. A second growth condition is determined based on first distance E1 measured. The second growth condition is used to manufacture epitaxial substrate 200 shown in FIG. 4. From another viewpoint, it can be said that silicon carbide epitaxial substrate 100 is used as a dummy substrate for determining the second growth condition. On the other hand, epitaxial substrate 200 is used to manufacture, for example, a silicon carbide semiconductor device, and will finally constitute a portion of the silicon carbide semiconductor device. It should be noted that silicon carbide epitaxial substrate 100 is not normally used as a portion of a silicon carbide semiconductor device; however, silicon carbide epitaxial substrate 100 may constitute a portion of a silicon carbide semiconductor device.

In the step (S30) of determining the growth condition, when it is desired to attain a longer second distance E2 (see FIG. 4) of epitaxial substrate 200 than first distance E1 (see FIG. 2) of silicon carbide epitaxial substrate 100, the second growth condition is determined such that the time of epitaxial growth is longer than that of the first growth condition, for example. On the other hand, when it is desired to attain a shorter second distance E2 than first distance E1, the second growth condition is determined such that the time of epitaxial growth is shorter than that of the first growth condition, for example. It should be noted that the second growth condition may be determined by changing at least one of the flow rate of the source gas, the flow rate of the dopant gas, and the flow rate of the carrier gas from the first growth condition.

Next, the step (S40) of performing epitaxial growth on the second silicon carbide substrate is performed. Second silicon carbide substrate 50 is prepared in the same manner as first silicon carbide substrate 30 in the step (S10) of preparing the silicon carbide epitaxial substrate. The epitaxial growth is performed using the hot wall type lateral CVD apparatus shown in FIG. 6. In the step (S40) of performing the epitaxial growth on the second silicon carbide substrate, the epitaxial growth is performed using the second growth condition. Thus, second silicon carbide epitaxial layer 60 is formed on second silicon carbide substrate 50. In this way, epitaxial substrate 200 (see FIG. 4) is manufactured.

### (Method of Manufacturing Silicon Carbide Semiconductor Device)

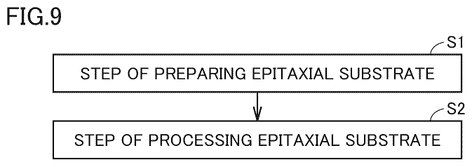

Next, a method of manufacturing a silicon carbide semiconductor device 400 according to the present embodiment will be described. FIG. 9 is a flowchart schematically showing the method of manufacturing silicon carbide semiconductor device 400 according to the present embodiment. As shown in FIG. 9, the method of manufacturing silicon carbide semiconductor device 400 according to the present embodiment mainly has a step (S1) of preparing the epitaxial substrate and a step (S2) of processing the epitaxial substrate.

First, the step (S1) of preparing the epitaxial substrate is performed. In the step (S1) of preparing the epitaxial substrate, epitaxial substrate 200 (see FIG. 4) according to the present embodiment is manufactured using the method of manufacturing epitaxial substrate 200 as shown in FIG. 7.

Next, the step (S2) of processing epitaxial substrate 200 is performed. Specifically, the following processes are performed to epitaxial substrate 200. First, ion implantation is performed into epitaxial substrate 200.

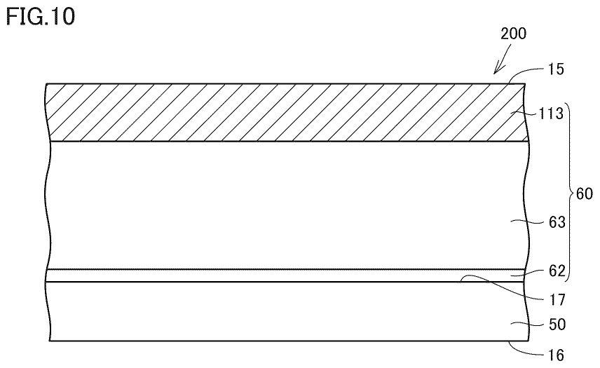

FIG. 10 is a schematic cross sectional view showing a step of forming a body region. In the step of forming the body region, ion implantation of a p type impurity such as aluminum is performed into fifth main surface 15 of second silicon carbide epitaxial layer 60, for example. Thus, a body region 113 having p type conductivity is formed. Portions in which no body region 113 is formed serve as second drift layer 63 and second buffer layer 62. The thickness of body region 113 is, for example, 0.9 μm. Second silicon carbide epitaxial layer 60 includes second buffer layer 62, second drift layer 63, and body region 113.

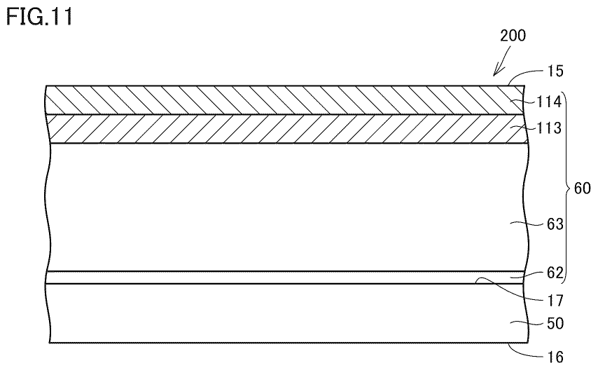

Next, a step of forming a source region is performed. FIG. 11 is a schematic cross sectional view showing the step of forming the source region. Specifically, ion implantation of an n type impurity such as phosphorus is performed into body region 113. Thus, a source region 114 having n type conductivity is formed. The thickness of source region 114 is, for example, 0.4 μm. The concentration of the n type impurity included in source region 114 is higher than the concentration of the p type impurity included in body region 113.

Next, ion implantation of a p type impurity such as aluminum is performed into source region 114 so as to form a contact region 118. Contact region 118 is formed to extend through source region 114 and body region 113 and come into contact with second drift layer 63. The concentration of the p type impurity included in contact region 118 is higher than the concentration of the n type impurity included in source region 114.

Next, activation annealing is performed to activate the impurities implanted by the ion implantation. A temperature of the activation annealing is, for example, 1500° C. or more and 1900° C. or less. A time of the activation annealing is, for example, about 30 minutes. An atmosphere of the activation annealing is, for example, an argon atmosphere.

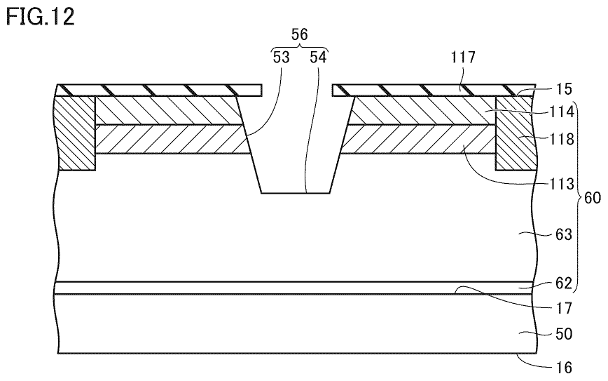

Next, a step of forming a trench in fifth main surface 15 of second silicon carbide epitaxial layer 60 is performed. FIG. 12 is a schematic cross sectional view showing the step of forming the trench in fifth main surface 15 of second silicon carbide epitaxial layer 60. A mask 117 provided with an opening is formed on fifth main surface 15 constituted of source region 114 and contact region 118. Source region 114, body region 113, and a portion of second drift layer 63 are removed by etching using mask 117. As the etching method, for example, inductively coupled plasma reactive ion etching can be used. Specifically, for example, inductively coupled plasma reactive ion etching using SF₆ or a mixed gas of SF₆ and O₂ as a reaction gas is used. A recess is formed in fifth main surface 15 by the etching.

Next, thermal etching is performed in the recess. The thermal etching may be performed, for example, by heating in an atmosphere including a reactive gas having at least one type of halogen atom with mask 117 being formed on fifth main surface 15. The at least one type of halogen atom includes at least one of a chlorine (Cl) atom and a fluorine (F) atom. The atmosphere includes, for example, Cl₂, BCl₃, SF₆, or CF₄. For example, the thermal etching is performed using a mixed gas of chlorine gas and oxygen gas as a reactive gas at a heat treatment temperature of, for example, 700° C. or more and 1000° C. or less. It should be noted that the reactive gas may include a carrier gas in addition to the chlorine gas and the oxygen gas. An exemplary, usable carrier gas is nitrogen gas, argon gas, helium gas, or the like.

As shown in FIG. 12, a trench 56 is formed in fifth main surface 15 by thermal etching. Trench 56 is defined by a side wall surface 53 and a bottom wall surface 54. Side wall surface 53 is constituted of source region 114, body region 113, and second drift layer 63. Bottom wall surface 54 is constituted of second drift layer 63. Next, mask 117 is removed from fifth main surface 15.

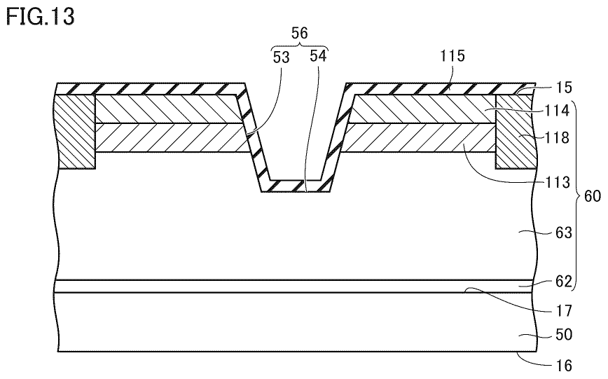

Next, a step of forming a gate insulating film is performed. FIG. 13 is a schematic cross sectional view showing the step of forming the gate insulating film. Specifically, epitaxial substrate 200 in which trench 56 is formed in fifth main surface 15 is heated in an atmosphere including oxygen at a temperature of, for example, 1300° C. or more and 1400° C. or less. Thus, a gate insulating film 115 is formed in contact with second drift layer 63 at bottom wall surface 54, in contact with each of second drift layer 63, body region 113, and source region 114 at side wall surface 53, and in contact with each of source region 114 and contact region 118 at fifth main surface 15.

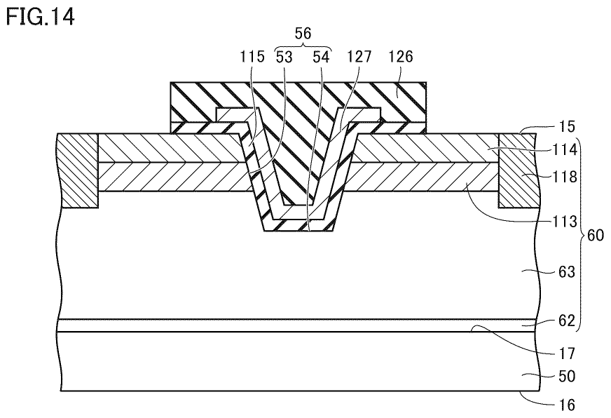

Next, a step of forming a gate electrode is performed. FIG. 14 is a schematic cross sectional view showing the step of forming the gate electrode and an interlayer insulating film. A gate electrode 127 is formed inside trench 56 so as to be in contact with gate insulating film 115. Gate electrode 127 is disposed inside trench 56, and is formed on gate insulating film 115 so as to face each of side wall surface 53 and bottom wall surface 54 of trench 56. Gate electrode 127 is formed by, for example, an LPCVD (Low Pressure Chemical Vapor Deposition) method.

Next, an interlayer insulating film 126 is formed. Interlayer insulating film 126 is formed to cover gate electrode 127 and be in contact with gate insulating film 115. Interlayer insulating film 126 is formed by, for example, a chemical vapor deposition method. Interlayer insulating film 126 is composed of, for example, a material including silicon dioxide. Next, portions of interlayer insulating film 126 and gate insulating film 115 are etched to form an opening above source region 114 and contact region 118. Thus, contact region 118 and source region 114 are exposed from gate insulating film 115.

Next, a step of forming a source electrode is performed. A source electrode 116 is formed in contact with each of source region 114 and contact region 118.

Source electrode 116 is formed by, for example, a sputtering method. Source electrode 116 is composed of, for example, a material including Ti (titanium), Al (aluminum), and Si (silicon).

Next, alloying annealing is performed. Specifically, source electrode 116 in contact with each of source region 114 and contact region 118 is held at a temperature of, for example, 900° C. or more and 1100° C. or less for about 5 minutes. Thus, at least a portion of source electrode 116 is silicided. In this way, source electrode 116 in ohmic contact with source region 114 is formed. Source electrode 116 may be in ohmic contact with contact region 118.

Next, a source wiring 119 is formed. Source wiring 119 is electrically connected to source electrode 116. Source wiring 119 is formed to cover source electrode 116 and interlayer insulating film 126.

Next, a step of forming a drain electrode is performed. First, sixth main surface 16 of second silicon carbide substrate 50 is polished. Thus, the thickness of second silicon carbide substrate 50 is reduced. Next, a drain electrode 123 is formed. Drain electrode 123 is formed in contact with sixth main surface 16. In this way, silicon carbide semiconductor device 400 according to the present embodiment is manufactured.

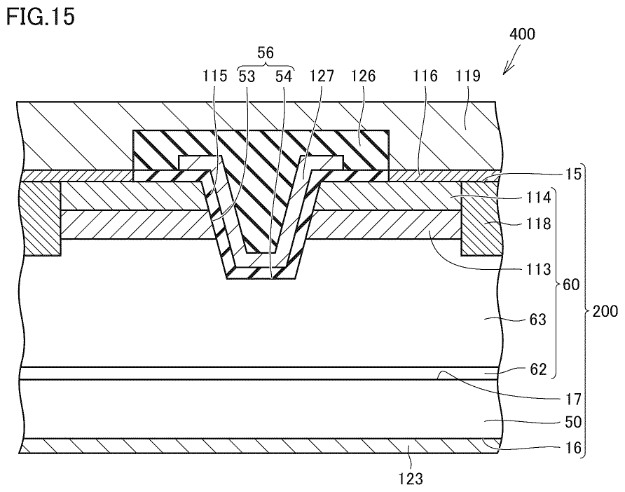

FIG. 15 is a schematic cross sectional view showing a configuration of the silicon carbide semiconductor device according to the present embodiment. Silicon carbide semiconductor device 400 is, for example, a MOSFET (Metal Oxide Semiconductor Field Effect Transistor). Silicon carbide semiconductor device 400 mainly has epitaxial substrate 200, gate electrode 127, gate insulating film 115, source electrode 116, drain electrode 123, source wiring 119, and interlayer insulating film 126. Epitaxial substrate 200 has second buffer layer 62, second drift layer 63, body region 113, source region 114, and contact region 118. Silicon carbide semiconductor device 400 may be, for example, an IGBT (Insulated Gate Bipolar Transistor) or the like.

Next, functions and effects of silicon carbide epitaxial substrate 100, the method of manufacturing an epitaxial substrate, and the method of manufacturing a silicon carbide semiconductor device according to the present embodiment will be described.

In an epitaxial substrate used in a power device such as a MOSFET, the concentration of an n type impurity in a buffer layer may be increased so as to suppress movement of positive holes from the buffer layer to a drift layer during an operation of the power device. Thus, a basal plane dislocation can be suppressed from becoming a stacking fault due to the positive holes reaching the drift layer. However, in this case, a difference between a concentration of an n type impurity in the buffer layer and a concentration of an n type impurity in the silicon carbide substrate is small. This leads to a decreased reflectance of infrared light at an interface between the buffer layer and the silicon carbide substrate, thus resulting in a decreased precision of measurement for the thickness of the silicon carbide epitaxial layer using an FTIR.

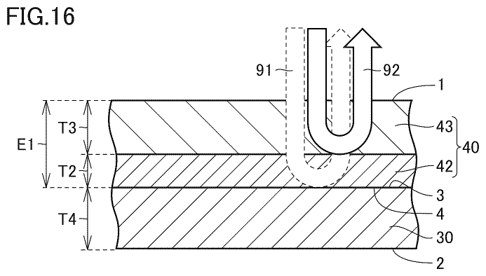

FIG. 16 is a schematic cross sectional view showing a step of measuring a first distance E1 in a silicon carbide epitaxial substrate 100 according to a comparative example. Silicon carbide epitaxial substrate 100 according to the comparative example shown in FIG. 16 does not have first boundary layer 41. As shown in FIG. 16, when first boundary layer 41 is not included, first buffer layer 42 is in contact with first silicon carbide substrate 30. In FIG. 16, a second arrow 92 represents infrared light reflected at an interface between first drift layer 43 and first buffer layer 42.

When silicon carbide epitaxial substrate 100 does not have first boundary layer 41 and a difference between concentration C2 of the n type impurity in first buffer layer 42 and concentration C4 of the n type impurity in first silicon carbide substrate 30 is small, the intensity of the infrared light (first arrow 91) reflected at the interface between first buffer layer 42 and first silicon carbide substrate 30 is decreased. Thus, an influence of the infrared light (second arrow 92) reflected at the interface between first drift layer 43 and first buffer layer 42 is increased in the FTIR. In other words, the intensity of the infrared light (first arrow 91) reflected at the interface between first buffer layer 42 and first silicon carbide substrate 30 becomes small with respect to the intensity of the infrared light (second arrow 92) reflected at the interface between first drift layer 43 and first buffer layer 42. This leads to a small interference between the infrared light reflected at first main surface 1 and the infrared light (first arrow 91) reflected at the interface between first buffer layer 42 and first silicon carbide substrate 30, thus resulting in decreased precision of measurement for first distance E1.

In silicon carbide epitaxial substrate 100 according to the present embodiment, first silicon carbide epitaxial layer 40 has first boundary layer 41. The concentration of the n type impurity in first boundary layer 41 is higher than the concentration of the n type impurity in first buffer layer 42. Thus, the reflectance of the infrared light (first arrow 91) at the interface (first interface 9) between first boundary layer 41 and first buffer layer 42 can be improved. Therefore, the intensity of the infrared light (first arrow 91) reflected at the first interface 9 becomes large with respect to the intensity of the infrared light (second arrow 92) reflected at the interface between first drift layer 43 and first buffer layer 42. Thus, the interference between the infrared light reflected at first main surface 1 and the infrared light (first arrow 91) reflected at first interface 9 becomes large, thereby improving the precision of measurement for first distance E1. As a result, the precision of measurement for the thickness of first silicon carbide epitaxial layer 40 can be improved.

In silicon carbide epitaxial substrate 100 according to the present embodiment, concentration C2 of the n type impurity in first buffer layer 42 is 3×10¹⁸/cm³ or more. Thus, even when concentration C2 of the n type impurity in first buffer layer 42 is high, the precision of measurement for the thickness of first silicon carbide epitaxial layer 40 can be suppressed from being decreased.

As the value obtained by subtracting concentration C2 of the n type impurity in first buffer layer 42 from concentration C3 of the n type impurity in first boundary layer 41 is larger, the reflectance of the infrared light at interface 9 between first boundary layer 41 and first buffer layer 42 can be more improved. In silicon carbide epitaxial substrate 100 according to the present embodiment, the value obtained by subtracting concentration C2 of the n type impurity in first buffer layer 42 from concentration C3 of the n type impurity in first boundary layer 41 is 1×10¹⁸/cm³ or more. Therefore, the precision of measurement for first distance E1 can be improved.

When concentration C3 of the n type impurity in first boundary layer 41 is too high and the thickness of first boundary layer 41 is too large, stacking faults formed in first silicon carbide epitaxial layer 40 may be increased during epitaxial growth. In silicon carbide epitaxial substrate 100 according to the present embodiment, first boundary layer 41 has a thickness of 5 μm or less. Therefore, the increase in stacking faults in first silicon carbide epitaxial layer 40 can be suppressed.

The method of manufacturing epitaxial substrate 200 according to the present embodiment includes: the step of measuring first distance E1 using silicon carbide epitaxial substrate 100; and the step of determining the growth condition based on first distance E1. Since the growth condition for second silicon carbide epitaxial layer 60 is thus determined based on first distance E1, precision for second distance E2 can be improved.

### EXAMPLES

### (Preparation of Samples)

First, silicon carbide epitaxial substrates 100 according to samples 1 and 2 were prepared. Silicon carbide epitaxial substrate 100 according to sample 1 is a comparative example. Silicon carbide epitaxial substrate 100 according to sample 2 is an example of the present disclosure. The configuration of silicon carbide epitaxial substrate 100 according to sample 1 was the configuration of silicon carbide epitaxial substrate 100 shown in FIG. 16. The configuration of silicon carbide epitaxial substrate 100 according to sample 2 was the configuration of silicon carbide epitaxial substrate 100 shown in FIGS. 1 to 3. Silicon carbide epitaxial substrate 100 according to sample 1 does not have first boundary layer 41. Silicon carbide epitaxial substrate 100 according to sample 2 has first boundary layer 41.

In each of silicon carbide epitaxial substrates 100 according to samples 1 and 2,concentration C1 of the n type impurity in first drift layer 43 was about 2×10¹⁶/cm³. In each of silicon carbide epitaxial substrates 100 according to samples 1 and 2,concentration C2 of the n type impurity in first buffer layer 42 was about 7×10¹⁸/cm³. In each of silicon carbide epitaxial substrates 100 according to samples 1 and 2,concentration C4 of the n type impurity in first silicon carbide substrate 30 was about 7×10¹⁸/cm³. In silicon carbide epitaxial substrate 100 according to sample 2,concentration C3 of the n type impurity in first boundary layer 41 was about 1×10¹⁹/cm³.

### (Experiment Method)

Each of silicon carbide epitaxial substrates 100 according to samples 1 and 2 was irradiated with infrared light using a Fourier transform infrared spectrometer (IRPrestige-21) provided by Shimadzu Corporation. The intensity of the infrared light reflected from silicon carbide epitaxial substrate 100 was measured for each wavenumber. A measurement wavenumber range was in a range of 4700 cm⁻¹ to 650 cm⁻¹. A calculation wavenumber range was from 3400 cm⁻¹ to 2400 cm⁻¹. A wavenumber interval was 4 cm⁻¹. An incident angle of the infrared light was 25°.

### (Experiment Result)

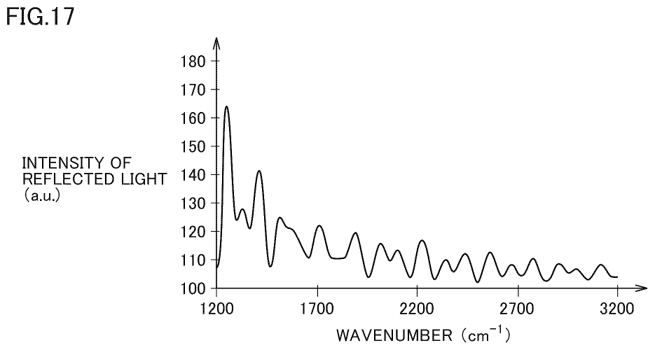

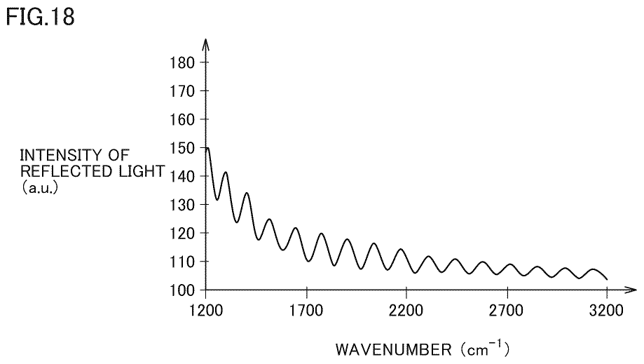

FIG. 17 is a graph showing a measurement result in silicon carbide epitaxial substrate 100 according to sample 1 by an FTIR. FIG. 18 is a graph showing a measurement result in silicon carbide epitaxial substrate 100 according to sample 2 by the FTIR. In each of FIGS. 17 and 18, the vertical axis represents the intensity of the reflected light, and the horizontal axis represents the wavenumber of the reflected light.

As shown in FIGS. 17 and 18, in silicon carbide epitaxial substrate 100 according to sample 2, it was confirmed that the intensity spectrum of the reflected light with respect to the wavenumber becomes more periodic than that in silicon carbide epitaxial substrate 100 according to sample 1.

In the FTIR, first distance E1 is calculated based on the intensity spectrum of the reflected light with respect to the wavenumber. Specifically, first distance E1 is calculated based on the number of local maximum values of the intensity spectrum in the calculation wavenumber range. Therefore, in silicon carbide epitaxial substrate 100 according to sample 2, first distance E1 can be measured more precisely than in silicon carbide epitaxial substrate 100 according to sample 1.

In view of the results above, it was confirmed that the precision of measurement for first distance E1 of the silicon carbide epitaxial layer was improved in silicon carbide epitaxial substrate 100 according to the example of the present disclosure as compared with silicon carbide epitaxial substrate 100 according to the comparative example.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface; 2: second main surface; 3: third main surface; 4: fourth main surface; 6: outer peripheral edge; 7: orientation flat; 8: arc-shaped portion; 9: first interface (interface); 15: fifth main surface; 16: sixth main surface; 17: seventh main surface; 18: eighth main surface; 19: second interface; 30: first silicon carbide substrate; 40: first silicon carbide epitaxial layer; 41: first boundary layer; 42: first buffer layer; 43: first drift layer; 50: second silicon carbide substrate; 53: side wall surface; 54: bottom wall surface; 56: trench; 60: second silicon carbide epitaxial layer; 61: second boundary layer; 62: second buffer layer; 63: second drift layer; 91: first arrow; 92: second arrow; 100: silicon carbide epitaxial substrate; 101: first direction; 102: second direction; 113: body region; 114: source region; 115: gate insulating film; 116: source electrode; 117: mask; 118: contact region; 119: source wiring; 123: drain electrode; 126: interlayer insulating film; 127: gate electrode; 200: epitaxial substrate; 201: reaction chamber; 202: stage; 203: heating element; 204: quartz tube; 205: inner wall surface; 207: gas introduction port; 208: gas discharging port; 209: rotation shaft; 210: susceptor; 231: first gas supply unit; 232: second gas supply unit; 233: third gas supply unit; 234: fourth gas supply unit; 235: gas supply unit; 241: first gas flow rate control unit; 242: second gas flow rate control unit; 243: third gas flow rate control unit; 244: fourth gas flow rate control unit; 245: control unit; 300: manufacturing apparatus; 400: silicon carbide semiconductor device; C1: first concentration; C2: second concentration; C3: third concentration; C4: fourth concentration; D1: first depth; D2: second depth; D3: third depth; E1: first distance; E2: second distance; T1: first thickness; T2: second thickness; T3: third thickness; T4: fourth thickness; T5: fifth thickness; T6: sixth thickness; T7: seventh thickness; T8: eighth thickness; W: maximum diameter.

1. A silicon carbide epitaxial substrate comprising:
a silicon carbide substrate; and
a silicon carbide epitaxial layer provided on the silicon carbide substrate, wherein
the silicon carbide epitaxial layer includes
a boundary layer provided on the silicon carbide substrate,
a buffer layer provided on the boundary layer, and
a drift layer provided on the buffer layer,
a concentration of an n type impurity in the buffer layer is 3×10¹⁸/cm³ or more, and
a concentration of an n type impurity in the boundary layer is higher than the concentration of the n type impurity in the buffer layer.

2. The silicon carbide epitaxial substrate according to claim 1, wherein the concentration of the n type impurity in the boundary layer is higher than a concentration of an n type impurity in the silicon carbide substrate.

3. The silicon carbide epitaxial substrate according to claim 1, wherein a value obtained by subtracting the concentration of the n type impurity in the buffer layer from the concentration of the n type impurity in the boundary layer is 1×10¹⁸/cm³ or more.

4. The silicon carbide epitaxial substrate according to claim 1, wherein a thickness of the boundary layer is 0.1 μm or more and 5 μm or less.

5. The silicon carbide epitaxial substrate according to claim 1, wherein the concentration of the n type impurity in the buffer layer is higher than a concentration of an n type impurity in the drift layer.

6. The silicon carbide epitaxial substrate according to claim 1, wherein the concentration of the n type impurity in the boundary layer is 5×10¹⁸/cm³ or more and 1×10²⁰/cm³ or less.

7. The silicon carbide epitaxial substrate according to claim 1, wherein the concentration of the n type impurity in the buffer layer is 1×10¹⁹/cm³ or less.

8. The silicon carbide epitaxial substrate according to claim 1, wherein a concentration of an n type impurity in the drift layer is 1×10¹⁵/cm³ or more and 5×10¹⁶/cm³ or less.

9. A method of manufacturing an epitaxial substrate, the method comprising:
preparing the silicon carbide epitaxial substrate according to claim 1;
measuring a distance from an interface between the boundary layer and the buffer layer to a surface of the silicon carbide epitaxial layer using the silicon carbide epitaxial substrate;
determining a growth condition based on the distance measured; and
performing epitaxial growth using the growth condition determined.

10. A method of manufacturing a silicon carbide semiconductor device, the method comprising:
manufacturing an epitaxial substrate using the method of manufacturing an epitaxial substrate according to claim 9; and
processing the epitaxial substrate.
